(19) United States
(12) Patent Application Publication
(10) Pub. No.: US 2008/0002843 A1
(43) Pub. Date: Jan. 3, 2008

(54) Ripple digital amplifier system

(76) Inventor: Tsung-Ming Cheng, Taoyuan City (TW)

Correspondence Address: TROXELL LAW OFFICE PLLC, SUITE 1404, 5205 LEESBURG PIKE, FALLS CHURCH, VA, 22041, US

(21) Appl. No.: 11/478,638

(22) Filed: Jul. 3, 2006

(51) Int. Cl. H03F 21/00; H04R 3/00

(52) U.S. Cl. 381/120; 381/111

(57) ABSTRACT

A ripple digital amplifier system includes one or multiple amplifier, one or multiple I/O process unit, and one or multiple transmission unit; the I/O process unit being built in the amplifier and including an audio receiving unit, an audio signal converting unit, an audio and output unit; and the transmission unit being disposed between every pair of amplifiers to transmit audio to each amplifier.

### BACKGROUND OF THE INVENTION

(a) Field of the Invention

The present invention is related to a ripple digital amplifier system, and more particularly to one that transmits audio signals by means of ripple digital transmission to one or multiple amplifier in a fashion of one-on-one or one-on-many fashion for achieving purposes of delivering complete audio, fast transmission, easy management, and advanced use of its power.

(b) Description of the Prior Art

In the installation of an amplifier in a conventional listening space involves analog process; wherein, the compound source of the analog audio is processed and transmitted through analog audio transmission conductor to the amplifier where the sound is reproduced. However, in the transmission of analog signals, signal decay resulted from the resistance of the metal conductor must be overcome. To ensure of integral audio signals, specification of the metal conductor or the audio source output power must be solved depending on the range of the transmission.

To minimize the distortion of analog audio, the audio source signals to each amplifier come from the audio source main unit, meaning, a set of metal conductor must be assigned to each amplifier and more conductors are needed at where more amplifiers are installed to make management even more difficult.

Referring to FIG. 1 of the accompanying drawings, the prior art includes a main unit 1 of audio source signals. The main unit 1 contains an amplifier 10 to transmit audio and electric power to one or multiple passive loudspeaker 12 through an analog signal transmission conductor 11 before replaying the sound from a built-in speaker 13 in a flow as illustrated in FIG. 2. In the prior art as described above, the wiring is put under collective management. In practice, the collective management always winds up in chaos and incomplete audio transmission to compromise the pleasant enjoyment of music of the user.

### SUMMARY OF THE INVENTION

The primary purpose of the present invention is to provide a ripple digital amplifier system to transmit audio to one or multiple amplifiers in one-on-one or one-on-many fashion using ripple digital transmission to achieve the purposes of complete audio, fast transmission, easy management and advanced efficiency of use.

To achieve the purposes, the present invention includes one or multiple amplifier, one or multiple I/O(input/output) process unit, and one or multiple transmission unit.

The I/O process unit is built in the amplifier and includes an audio receiving unit, an audio converting unit, and an audio output unit.

### BRIEF DESCRIPTION OF THE DRAWINGS

FIG. 1 is a schematic view showing the prior art.

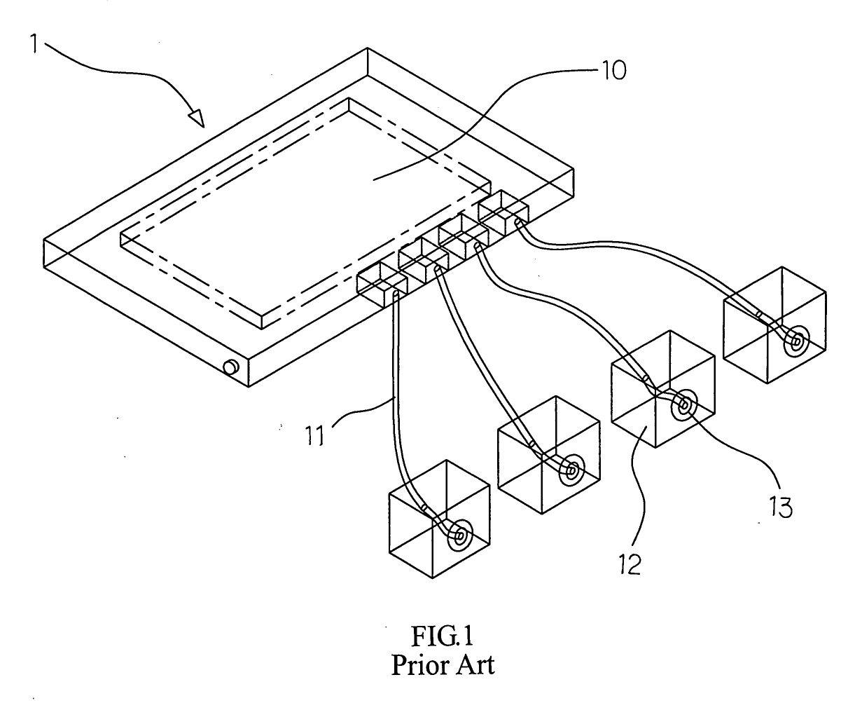

FIG. 2 is a flow chart showing the operation of the prior art.

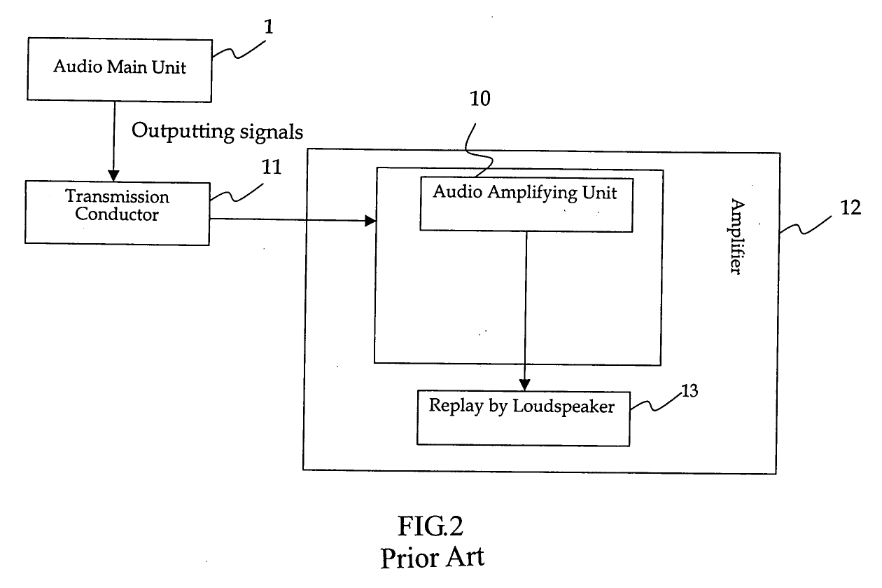

FIG. 3 is a perspective view of the present invention.

FIG. 4 is a flow chart of the operation of a first preferred embodiment of the present invention.

FIG. 5 is a flow chart of the operation of a second preferred embodiment of the present invention.

FIG. 6 is a schematic view showing the first preferred embodiment of the present invention.

FIG. 7 is a schematic view showing the second preferred embodiment of the present invention.

FIG. 8 is a schematic view showing a third preferred embodiment of the present invention.

### DETAILED DESCRIPTION OF THE PREFERRED EMBODIMENTS

A ripple digital amplifier system of the present invention includes one or multiple amplifiers, one or multiple I/O process unit, and one or multiple transmission unit.

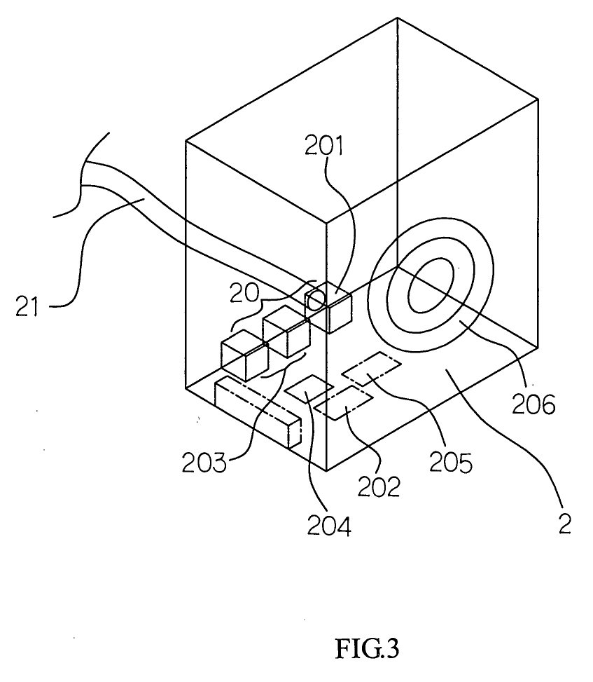

As illustrated in FIG. 3, the I/O process unit 20 is built in the amplifier 2 and contains an audio receiving unit 201, an audio converting unit 202, an audio output unit 203, another audio amplifying unit 204, and an audio process unit 205. The audio receiving unit 201 receives signals inputted from another amplifier 2 or audio source; the audio converting unit 202 converts the signals received; the audio output unit 203 outputs the signals converted; the transmission unit 21 disposed between every pair of amplifier to transmit signals to each amplifier 2; The amplifier 2 is connected to speaker driver unit(s) 206 and a ripple digital speaker consists both of them to work properly.

The amplifier 2 is capable of receiving analog, digital or optical signals, converting analog or optical signals into digital audio, and converts digital signals into analog or optical signals for output. Therefore, all analog, digital, or optical signals received or outputted by the amplifier 2 in the preferred embodiment are treated as the primary signals; and those digital or optical signals transmitted between any two ripple digital amplifiers are also treated as the primary signals in the preferred embodiment. If digital signals are transmitted, a metal conductor is used; and if optical signals are transmitted, a fiber conductor is used.

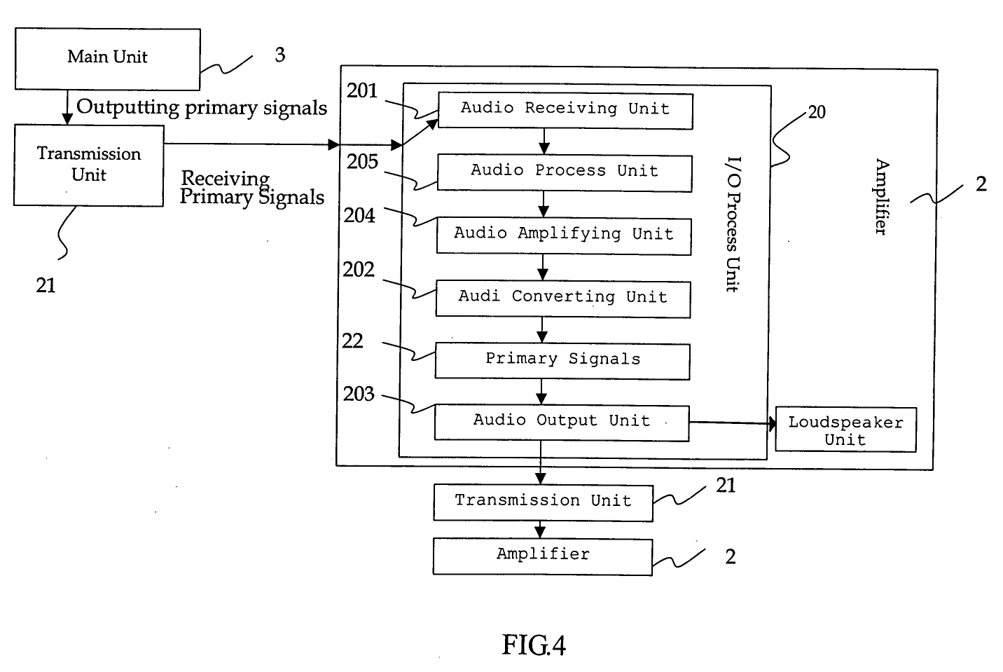

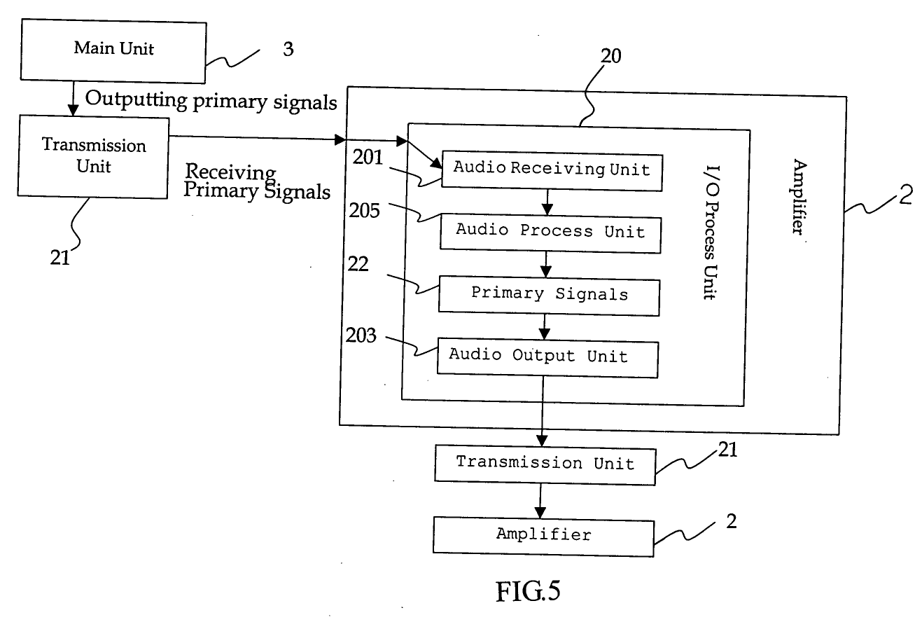

Now referring to FIG. 4 for a flow chart of the first preferred embodiment, the amplifier 2 receives the primary signals 22 of the original output from a main unit 3. The built in I/O process unit 20 of the amplifier 2 picks up the primary signals 22 received by the amplifier 2 at the audio receiving unit 201. Wherein, the I/O process unit 20 relates to a circuit board or an IC(integrated circuit), and the audio process unit 205 further receives the primary signals 22 to retrieve and transmit the entire primary signals 22 or any part of it to two destinations. One destination is the other audio amplifying unit 204 in the I/O process unit 20 where the audio is amplified and converted at the audio converting unit 202; the first signals 22 after the conversion are outputted through the audio output unit 203 to the loudspeaker unit 206 as illustrated in FIG. 4. Another designation is the audio output unit 203 where the entire or the given part of the first signals 22 is transmitted through the transmission unit 21 to a next ripple amplifier 2 as illustrated in FIG. 5.

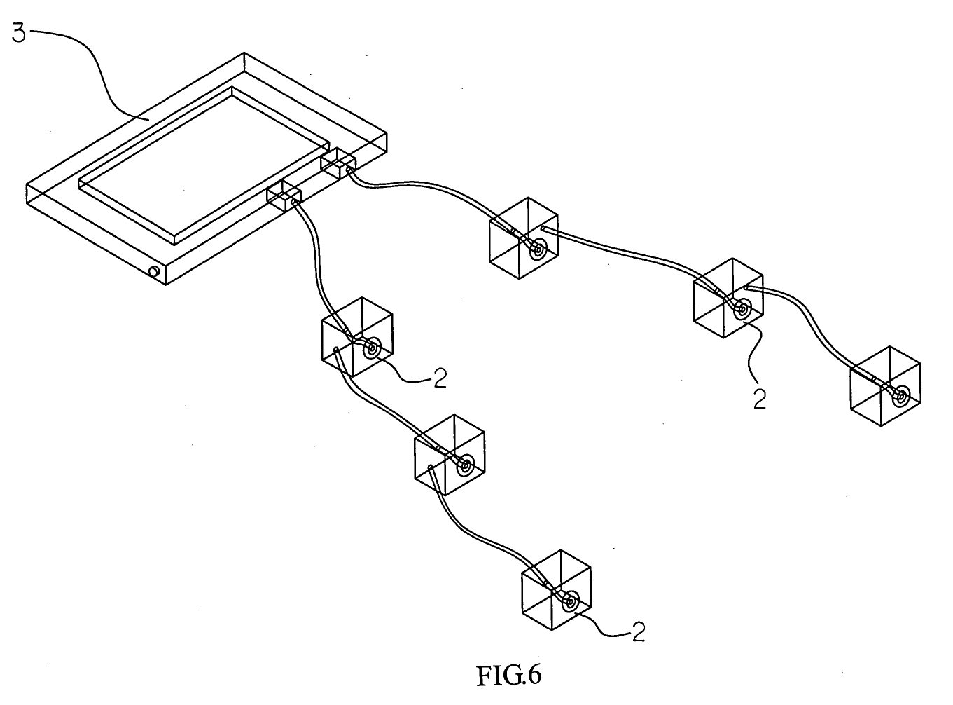

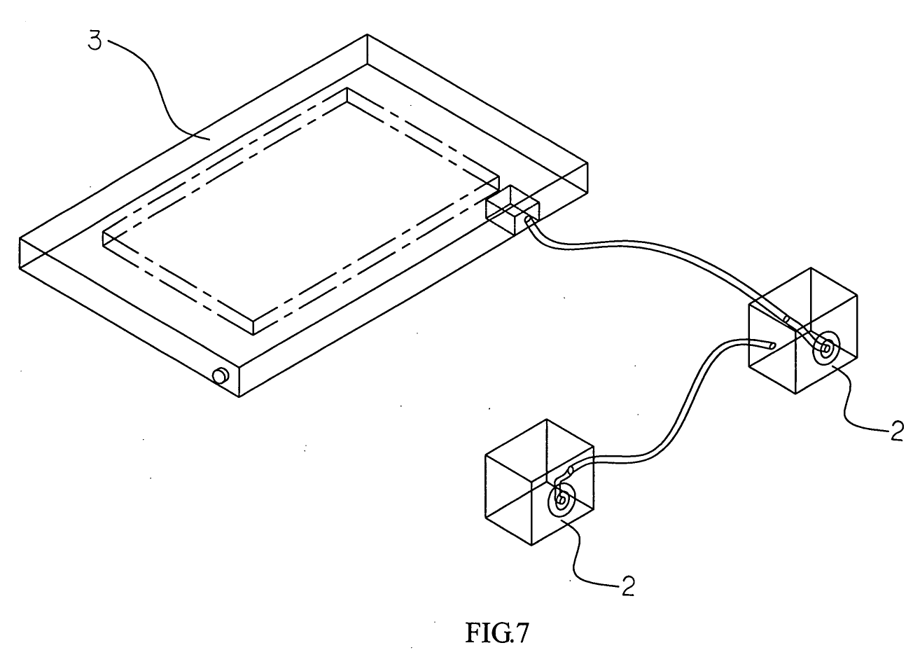

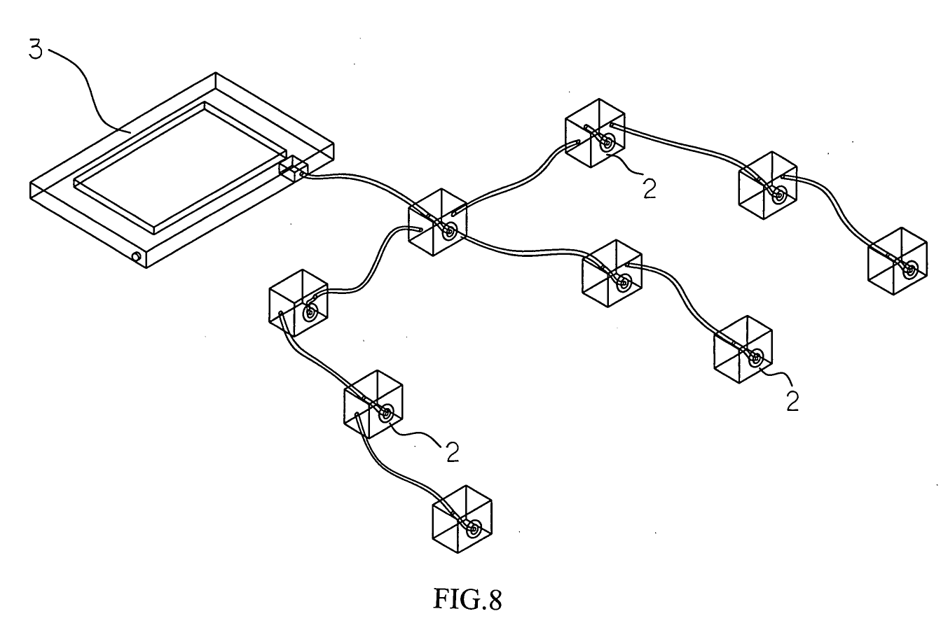

FIGS. 6, 7, and 8 respectively shows different wiring in the amplifier 2. As illustrated in FIG. 6, for the application in a replay device of two-channel audio source, the first preferred embodiment of the present invention is comprised of one-in and one-out ripple digital amplifier working on ripple digital transmission in series; wherein the main unit 3 transmits signals to the primary amplifier 2 where the signals are transmitted to a secondary amplifier 2. The ripple digital transmission of the second preferred embodiment as illustrated in FIG. 7 relates to a one-in and two-out transmission method. As for a third preferred embodiment of the present invention illustrated in FIG. 8, the ripple digital transmission is executed in parallel. Wherein, the main unit 3 transmits signals to the primary amplifier 2 where the signals are transmitted to another primary amplifier 2; then each primary amplifier 2 transmits its signals to each secondary amplifier 2 in a transmission pattern of one-in and multiple-out that is applicable to a replay device of two or more than two channels.

According to the description given above, the present invention corrects the flaws found with the prior art and achieves the purposes of fast transmission, easy management, and advanced use efficiency.

The prevent invention provides an improved structure of a ripple digital amplifier system, and the application for a utility patent is duly filed accordingly. However, it is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

I claim,

1. A ripple digital amplifier system includes one or multiple amplifiers; one or multiple I/O process unit built in the amplifier containing an audio receiving unit to receive signals inputted into the amplifier, an audio converting unit to execute the digital/analog conversion for the signals received, and an audio output unit to output the signals converted; and one or multiple transmission unit disposed between every pair of amplifiers to transmit signals to each amplifier.

2. A ripple digital amplifier system of claim 1, wherein the primitive input signals is outputted from a main unit.

3. A ripple digital amplifier system of claim 1, wherein the amplifier is capable of receiving analog, digital or optical signals; and converting analog or optical signals into digital signals, or vice versa, or converting analog or digital into optical signals for output.

4. A ripple digital amplifier system-of claim 1, wherein all the analog, digital or optical signals received and outputted by the amplifier, and those digital or optical signals transmitted among all the ripple digital amplifiers are all treated as the primary signals.

5. A ripple digital amplifier system of claim 1, wherein the I/O process unit relates to a circuit board or IC.

6. A ripple digital amplifier system of claim 1, wherein the I/O process unit further includes an audio amplifying unit and an audio process unit.

7. A ripple digital amplifier system of claim 1, wherein the amplifier contains a loudspeaker unit.

8. A ripple digital amplifier system of claim 7 wherein digital signals are transmitted in metal conductor.

9. A ripple digital amplifier system of claim 7 wherein optical signals are transmitted in fiber conductor.
